(19) United States
(12) Patent Application Publication
(10) Pub. No.: US 2007/0131389 A1
(43) Pub. Date: Jun. 14, 2007

(54) Heat dissipating device and method of fabricating the same

(75) Inventors: Kuo-Hsin Chen, Jhonghe City (TW); Hsuan-Chih Lin, Jhonghe City (TW)

Correspondence Address: HDSL, 4331 STEVENS BATTLE LANE, FAIRFAX, VA, 22033, US

(73) Assignees: Kuo-Hsin Chen; Hsuan-Chih Lin; Hoff Thermal Solution Co., Ltd.

(21) Appl. No.: 11/297,402

(22) Filed: Dec. 9, 2005

(51) Int. Cl. H05K 7/20; F28D 15/00

(52) U.S. Cl. 165/104.33; 165/80.3; 361/700

(57) ABSTRACT

A heat dissipating device includes thermal conductive pipes and a plurality of thermal fin modules. Each thermal fin module made by pressing and stacking is mounted on the thermal conductive pipes. A retainer is located between each two thermal fin modules to compress the thermal fin module, so that a distance between two fins of the thermal fin module is reduced. Finally, a fixing plate is set above the last thermal fin module on the thermal conductive pipes to fix the thermal fin modules securely engaged with the thermal conductive pipes. Therefore, the assembled heat dissipating module could not be loosed and deformed during delivery and the engaging contact between the fins and the thermal conductive pipes are enhanced, so to increase the heat dissipating effect of the heat dissipating module.

### BACKGROUND OF THE INVENTION

1. Field of the Invention

The present invention relates to a heat dissipating device and a method of fabricating the same, and particularly relates to a method of fabricating a heat dissipating device including at least two thermal fin modules capable of being stably fixed on thermal conductive pipes.

2. Description of Related Art

Usually, in order to increase the heat dissipating speed, multiple thermal conductive pipe is passed through the fins of a thermal fin module. Therefore, the heat generated from a heat source could be dissipated through the thermal conductive pipe and the thermal fin module.

During assembling a heat dissipating device, first, a plurality of fins are pressed and stacked together to make the thermal fin module and through holes are correspondingly formed on the fins of the thermal fin module. Then, annular walls are respectively formed surrounding the through holes, and the thermal conductive pipes are passed through the fins. The annular wall of a lower fin is embedded into the gap between the thermal conductive pipe and the annular wall of an upper fin. Therefore, the fins are stacked together to be engaged with the thermal conductive pipes.

However, the structure assembled in the manner mentioned above is not compact enough, such that the fins could loose from the thermal conductive pipe or deform during delievery. Thus, the contact area of the thermal conductive pipes with the fins of the thermal fin module is reduced, so that the heat dissipating effect is not good. It is necessary to improve the assembling step to increase the contact area of the thermal conductive pipe with the fins and to induce an adhesive material so that the adhesion between the fins and the thermal conductive pipes can be improved.

### SUMMARY OF THE INVENTION

The present invention is to provide a heat dissipating device. The heat dissipating device comprises at least two thermal fin modules, at least one thermal conductive pipe, a retainer and a fixing plate. Each thermal fin module is made of a plurality of fins by pressing and stacking. Through holes are formed on each fin of the thermal fin module corresponding to the thermal conductive pipes. The fixing plate is set on the top of two thermal fin modules, wherein the fixing plate is thicker than each of the fins of the thermal fin module, and holes are formed on the fixing plate for the thermal conductive pipes to pass through. Therefore, the fins of the thermal fin module can be fixedly mounted with the thermal conductive pipes by the fixing plate.

The present invention is also to provide a method of fabricating a thermal fin module. First, a first thermal fin module made by pressing and stacking a plurality of fins is mounted on thermal conductive pipes. Next, a retainer is attached to the top surface of the first thermal fin module, and a compressing force is exerted on the first thermal fin module. Thereafter, a second thermal fin module made by pressing and stacking a plurality of fins is mounted on thermal conductive pipes to the first thermal fin module. Then, a fixing plate is set above the second thermal fin module on the thermal conductive pipes. Finally, the fixing plate set on the thermal fin module makes and the thermal fin module securely fixed on the thermal conductive pipes.

### BRIEF DESCRIPTION OF THE DRAWINGS

FIG. 1 is a perspective view showing a heat dissipating device according to the first embodiment of the present invention;

FIG. 2 is a cross-section view illustrating that a first thermal fin module is mounted on thermal conductive pipes according to the first embodiment of the present invention;

FIG. 3 is a partially magnified schematic drawing of FIG. 2;

FIG. 4 is a perspective view showing a retainer being mounted on the thermal conductive pipes to the first thermal fin module;

FIG. 5 is a perspective view showing a second thermal fin module is mounted on thermal conductive pipes to the first thermal fin module;

FIG. 6 is a perspective view illustrating that a fixing plate will be mounted on the thermal conductive pipes to the second thermal fin module;

FIG. 7 is a cross-section view illustrating the fixing plate mounted on the thermal conductive pipes;

FIG. 8 is a partially magnified schematic drawing of FIG. 6;

FIG. 9 is a cross-section view of a heat dissipating device according to the second embodiment of the present invention;

FIG. 10 is a cross-section view of a heat dissipating device according to the third embodiment of the present invention;

FIG. 11 is a perspective view showing a heat dissipating device according to the fourth embodiment of the present invention; and

FIG. 12 is a perspective view showing a heat dissipating device according to the fifth embodiment of the present invention.

### DETAILED DESCRIPTION OF THE PREFERRED EMBODIMENT

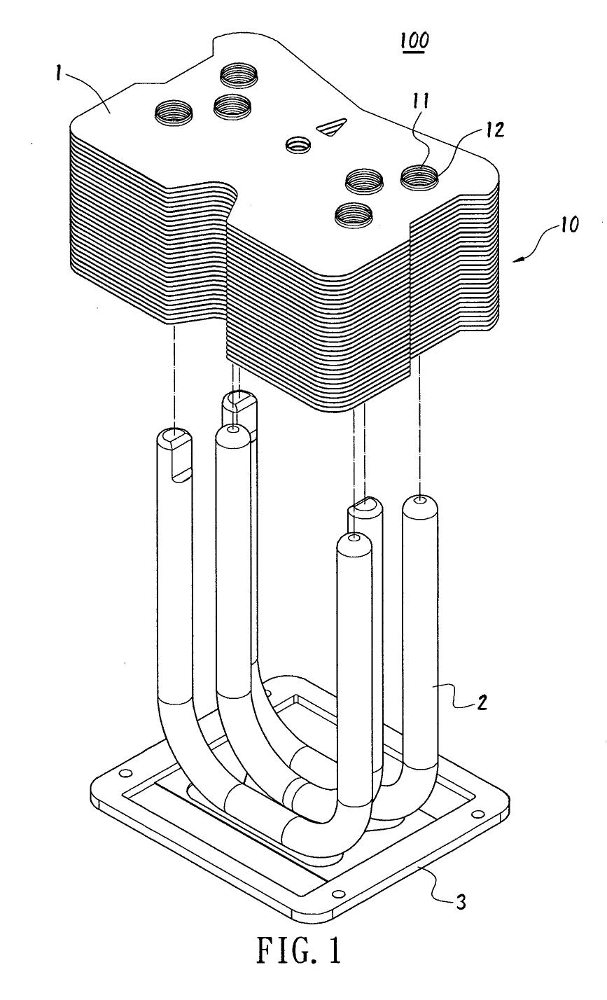

Please refer to FIGS. 1-12. According to the present invention, a method of fabricating a heat dissipating device comprises the following steps:

a) mounting a first thermal fin module 10 made by pressing and stacking a plurality of fins 1 on thermal conductive pipes 2;

b) setting a retainer 5 on the top surface of the first thermal fin module 10, and compressing downward the thermal fin module 10;

c) mounting a second thermal fin module 10′ made by pressing and stacking a plurality of fins 1′ on thermal conductive pipes 2 to locate above the first thermal fin module 10;

c) mounting a fixing plate 4 above the second thermal fin module 10′ on the thermal conductive pipes 2; and

d) setting the fixing plate 4 on the thermal fin module 10′ to make the first and the second thermal fin modules 10 and 10′ securely fixed on the thermal conductive pipes 2.

In FIG. 1, the thermal conductive pipes 2 pass through the fins 1, 1′ with a thickness of less than 0.2 mm. The fins 1, 1′ are used to dissipate heat from the thermal conductive pipes 2. The fins 1, 1′ and the thermal conductive pipes 2 are tightly connected, so as to reduce any gap between the fins 1, 1′ and the thermal conductive pipes 2. The thermal conductive pipes 2 can be water pipes or heat pipes. In the embodiment, the thermal conductive pipes 2 are preferably the heat pipes.

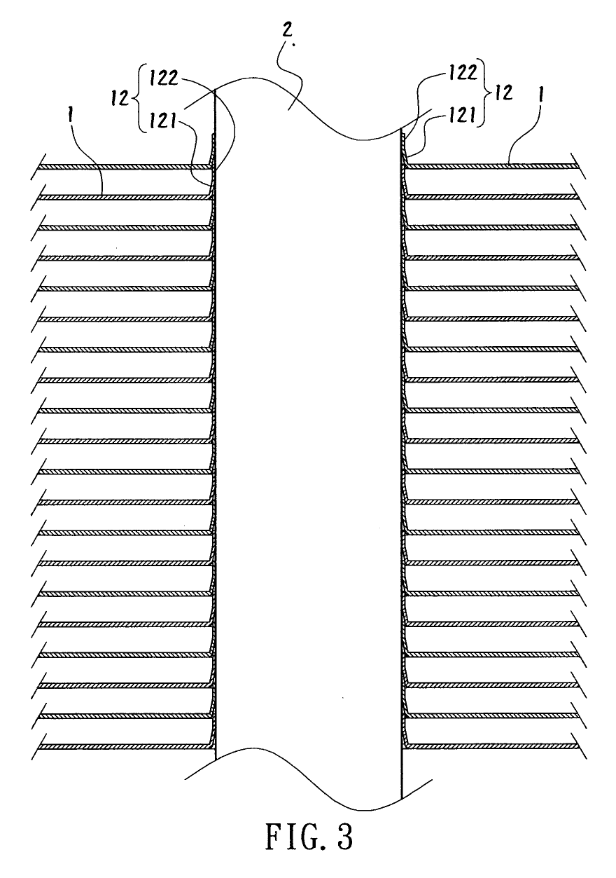

In the first preferred embodiment, the first and the second thermal fin modules 10, 10′ comprising a plurality of fins 1, 1′ are provided. Through holes 11, 11′ are formed on each of the fins 1, 1′ corresponding the locations of the thermal conductive pipes 2. Annular walls 12, 12′ with tapered shape are formed on each of the through holes 11, 11′ by a drawing process during forming the through holes 11, 11′. Each annular wall 12, 12′ comprises a taper portion 121, 121′ surrounding the top of the through holes 11, 11′ and a pressing portion 122, 122′ extending from the narrow top of the taper portion 121, 121′ (as shown in FIG. 3). After assembling the fins 1, 1′ to form the thermal fin module 10, 10′, each of the through holes 11, 11′ of an upper fin is seated on each of the pressing portions 122, 122′ of a lower fin. In addition, the thermal conductive pipes 2 are vertically installed on a thermal base 3, so as to form a heat dissipating device 100.

The retainer 5 is mounted on the thermal conductive pipes 2 to locate between two thermal fin modules 10 and 10′. A plurality of holes 51 are formed on the retainer 5, such that the thermal conductive pipes 2 could pass through the holes 51, respectively. A fixing plate 4 is installed on the top of the second thermal fin module 10′ after the thermal conductive pipes 2 pass through two thermal fin modules 10 and 10′. The fixing plate 4 is thicker than each of the fins 1, 1′. A plurality of holes 41 are formed on the fixing plate 4, such that the thermal conductive pipes 2 could pass through the holes, respectively.

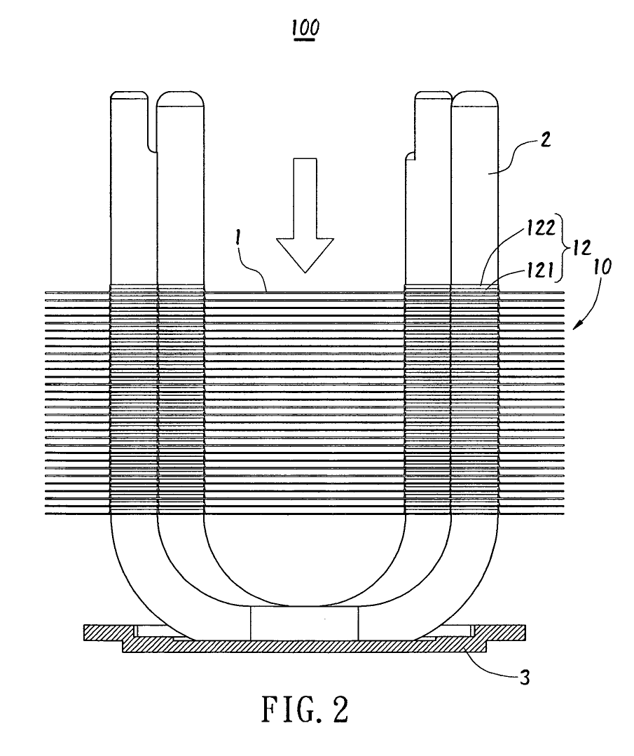

In FIG. 1 and FIG. 2, during the step of installing the first thermal conductive pipes 2 through the thermal fin module 10, the thermal conductive pipes 2 are passing from the wide base of the taper portions 121 of the annular walls 12 through the though holes 11 of the stacked fins 1. Since the narrower pressing portion 122 which has a size slightly smaller than the size of the thermal conductive pipes 2, after the fins are sequentially mounted to the thermal conductive pipes 2, the distance between the fins 1 is slightly prolonged during the passing step. Thus, the through holes 11 of the fins 1 and the thermal conductive pipes 2 are not tightly contacted, as shown in FIG. 3.

Preferably, a layer of thermal conductive material (not shown) is pasted on the surface of the thermal conductive pipes 2 before passing the thermal conductive pipes 2 through the through holes 11. The thermal conductive material comprising dense polymers, such as silicone oil, mineral oil, or polyethylene glycol (PEG), lubricates the thermal conductive pipes 2 and the through holes 11, such that the thermal conductive pipes 2 could pass through the through holes 11 easily. Furthermore, the dense polymers can fully fill up the gap between the thermal conductive pipes 2 and the pressing portions 122 of the fins 1, so as to increase the adhesion.

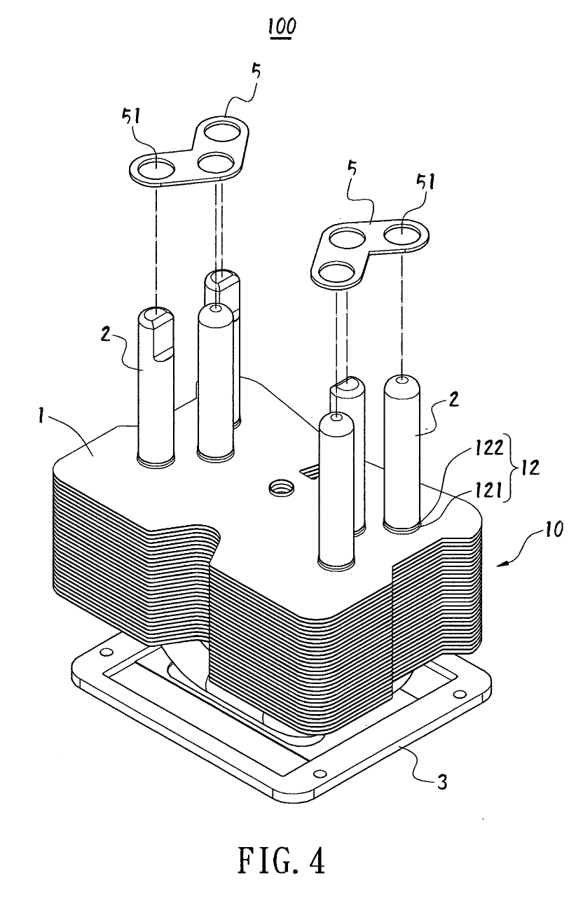

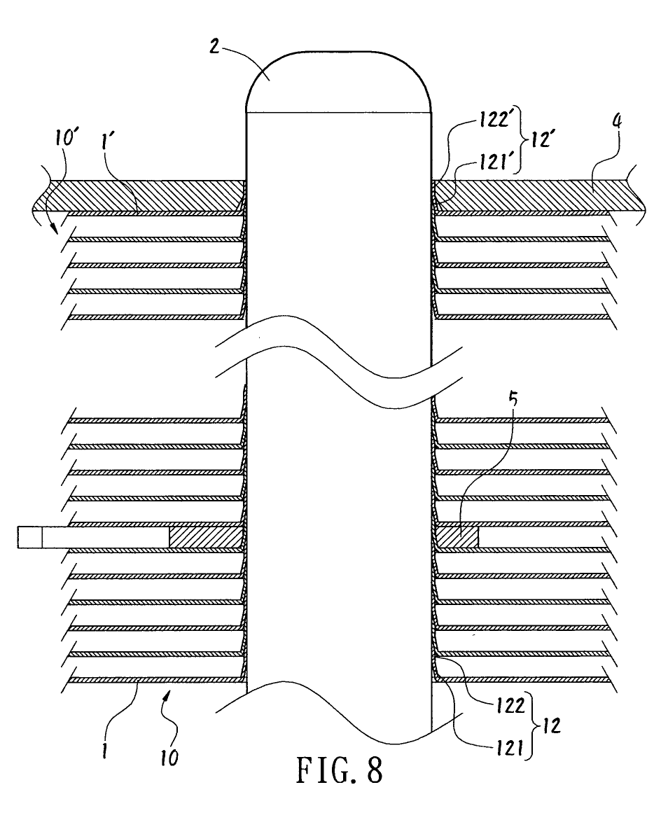

In FIG. 4, the retainer 5 is fixed on the upper layer of the fins 1. A compressing force is induced from the retainer 20 to press on the fins 1, such that the pressing portion 122 of each lower fin is embedded into the gap between the thermal conductive pipes 2 and taper portion 121 of each upper fin, as shown in FIG. 8. Thus, the distance between two fins 1 is reduced, and the adhesion between the thermal conductive pipes 2 and the fins 1 is improved.

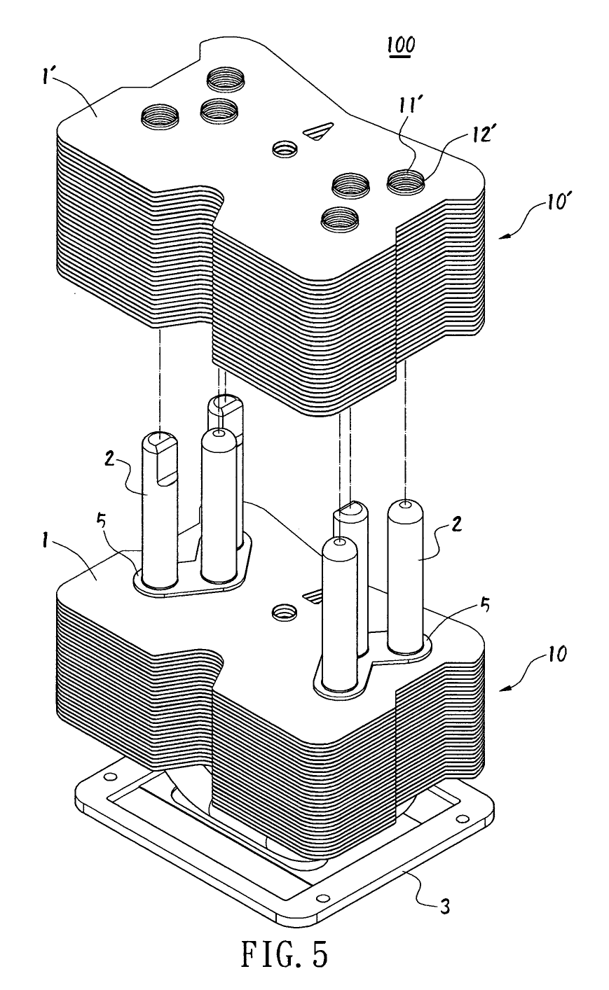

In FIG. 5, when the retainer 5 fixes the first thermal fin module 10 on the thermal conductive pipes 2, the second thermal fin module 10′ will be similarly mounted on thermal conductive pipes 2. The distance between the fins 1′ is slightly prolonged during the passing step. Thus, the through holes 11′ of the fins 1′ and the thermal conductive pipes 2 are also not tightly contacted.

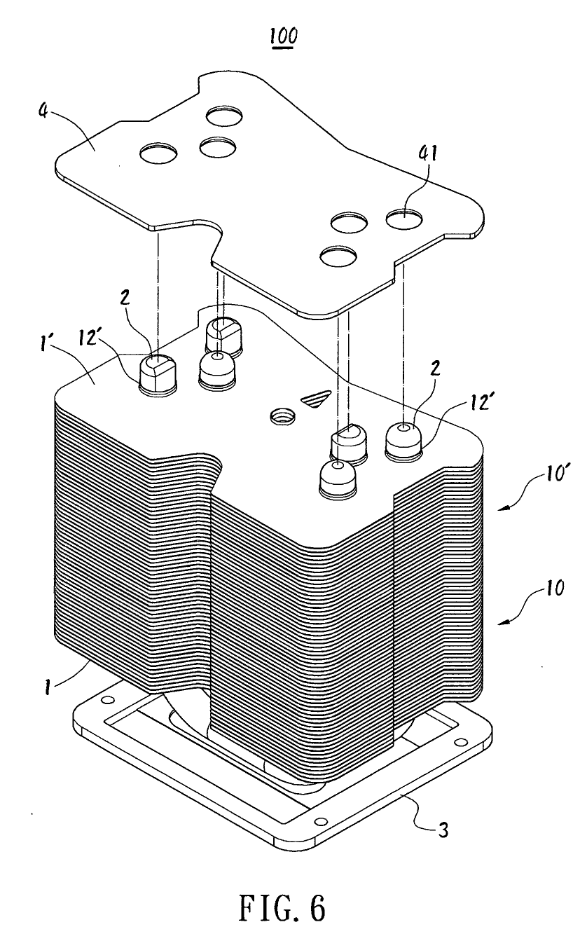

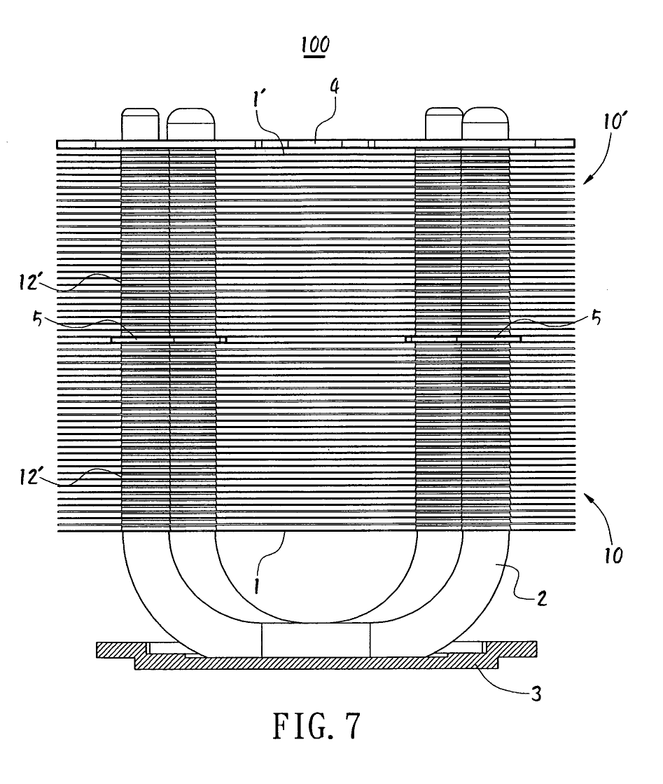

In FIG. 6 and FIG. 7, the fixing plate 4 is set on the thermal conductive pipes 2 to install the fixing plate 4 on the top of the second thermal fin module 10′ so that the pressing portion 122′ of each lower fin is embedded into the gap between the thermal conductive pipes 2 and taper portion 121′ of each upper fin, as shown in FIG. 8. Thus, the distance between two fins 1′ is also reduced.

Similarly, a layer of thermal conductive material (not shown) is pasted on the surface of the thermal conductive pipes 2 before passing the thermal conductive pipes 2 through the through holes 11′. As such, the adhesion between the thermal conductive pipes 2 and the fins 1 is also improved and the thermal fin module 10, 10′ and the thermal conductive pipes 2 are fixed and assembled. Moreover, an adhesive material is preferably pasted covering the sidewall of the holes 41 and 51 of the fixing plate 4 and the retainer 5, respectively , such that the adhesion between the fixing plate 4 and the fixing plate 5 and the thermal conductive pipes 2 is improved.

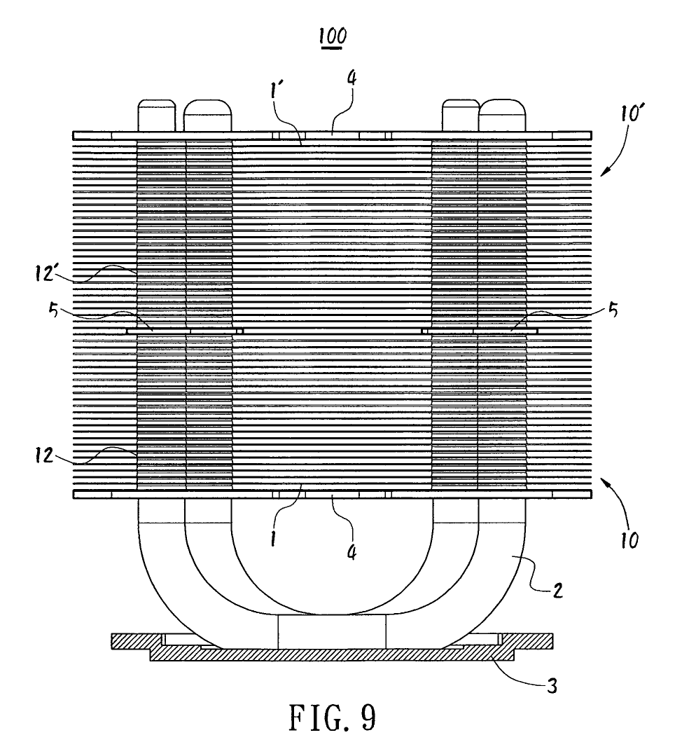

In FIG. 9, a cross-section view of the second embodiment of the present invention is shown. In the second embodiment, one more fixing plate 4 is further installed below the lower surface of the first thermal fin module 10. Thus, the fixing plates 4 are set on the thermal conductive pipes 2 to have the thermal fin modules 10 and 10′ sandwiched therebetween.

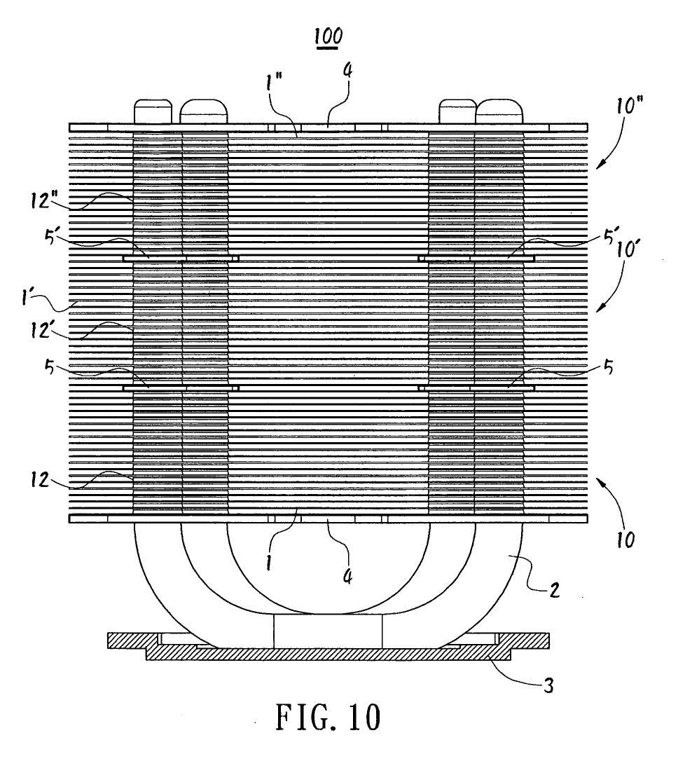

In FIG. 10, a cross-section view of the third embodiment of the present invention is shown, where there are three thermal fin modules 10, 10′ and 10″ provided. First, the fixing plate 4 is mounted on the thermal conductive pipes. Then, the first thermal fin module 10 is set on the thermal conductive pipes 2 by compressing. Next, the retainer 5 is fixed on the top of the surface of the first thermal fin module 10, and a compressing force is induced from the retainer 5 to press on the fins 1 of the first thermal fin module 10, such that the pressing portion 122 of the lower fin of the first thermal fin module 10 is embedded into the gap between the thermal conductive pipes 2 and taper portion 121 of the upper fin of the first thermal fin module 10. The annular walls 12 of the first thermal fin 10 are more tightly engaged with the thermal conductive pipes 2 in order.

The second thermal fin module 10′ is then similarly set on the thermal conductive pipes 2. Thus, the second thermal fin module 10′ is fixed and located above the first thermal fin module 10. Another retainer 5 is fixed on the second thermal fin module 10′. A compressing force is again induced from the retainer 5 to press on the fins 1′ of the second thermal fin module 10′, such that the pressing portion 122′ of the lower fin 1′ of the first thermal fin module 10′ is embedded into the gap between the thermal conductive pipes 2 and taper portion 121′ of the upper fin 1′ of the second thermal fin module 10′. The distance between the fins 1′ of the second thermal fin module 10′ is thus reduced. The annular walls 12′ of the second thermal fin module 10′ are more tightly engaged with the thermal conductive pipes 2 in order.

The third thermal fin module 10″ is then similarly set on the thermal conductive pipes 2. Thus, the third thermal fin module 10′ is fixed and located above the second thermal fin module 10′. Finally, another fixing plate 4 is set on the thermal conductive pipes 2 above the third thermal fin module 10″. As a result, the first, the second and the third thermal fin module 10, 10′ and 10″ are fixed and compressed on the thermal conductive pipes 2 by the fixing plates 4 and the retainers 5. Therefore, the annular walls of the first, the second and the third thermal fin module 10, 10′ and 10″ are all more tightly engaged with the thermal conductive pipes 2.

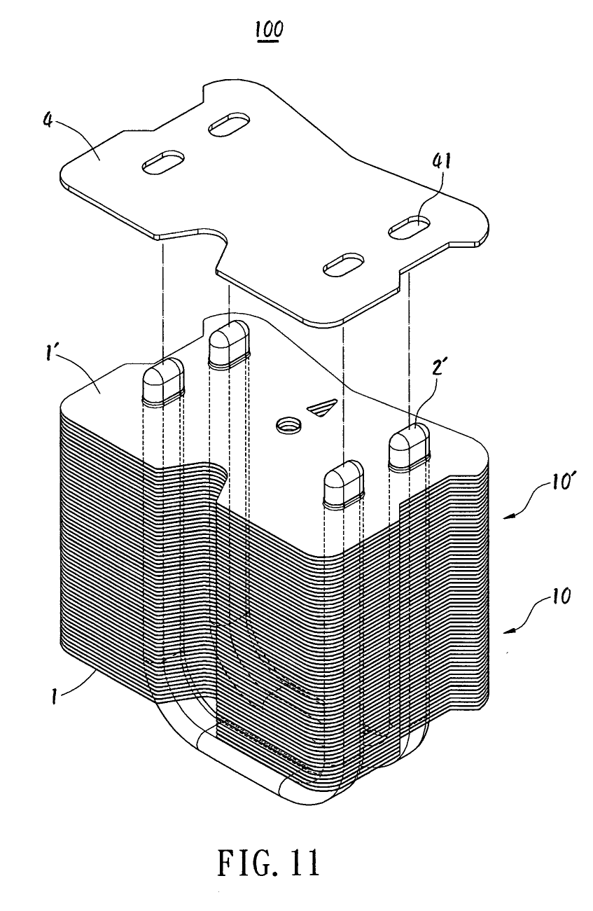

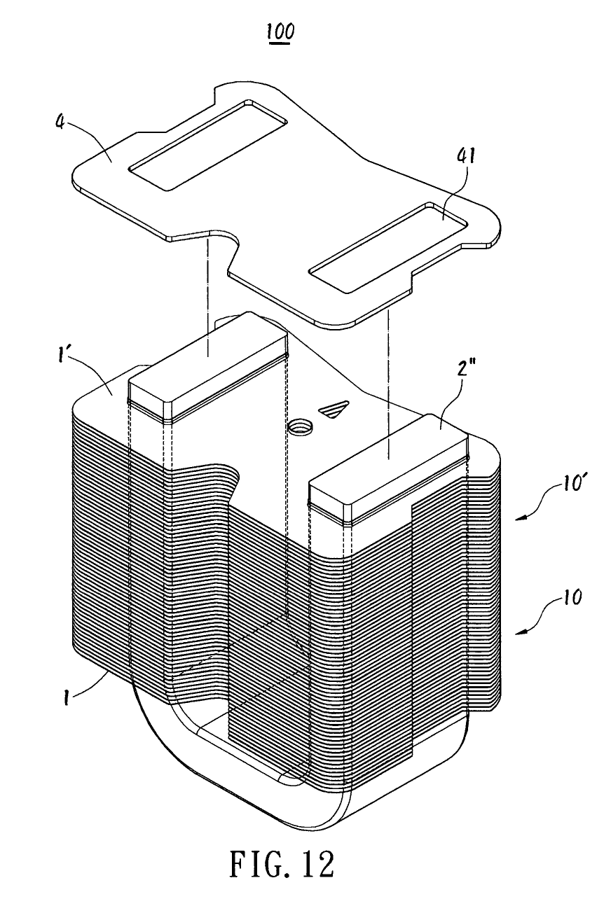

In the above embodiments of the present invention, the thermal conductive pipes 2 are, but not limited to, U-shaped circular tubes. For example, in FIG. 11, a perspective schematic view of the fourth embodiment of the present invention is shown, wherein the thermal conductive pipes 2′ are substantially U-shaped elliptic tubes. That is, the shapes of the through holes 11, 11′ of the fins 1, 1′ of the thermal fin module 10, 10′ and the holes 41 and 51 of the fixing plate 4 and the retainer, respectively, are formed in ellipse according to a cross sectional shape of the thermal conductive pipes 2′. In FIG. 12, a perspective schematic view of the fifth embodiment of the present invention is shown, wherein the thermal conductive pipes 2″, which can be called as the isothermal plate pipes, have rectangular plates in cross section. As such, the shapes of the through holes 11, 11′ of the fins 1, 1′ of the thermal fin module 10, 10′ and the holes 41 and 51 of the fixing plate 4 and the retainer, respectively, are formed in rectangle.

As mentioned above, the fins of the thermal fin module are fixed and set on the thermal conductive pipes by using the fixing plate and the retainer as a stopper, such that it prevents the thermal fin module from loosing and deforming during delivery, resulting in improvement of the yield rate of the products. Furthermore, the pressing portions of the annular walls of the fins are embedded into the gap between the taper portions of the annular walls of the fins and the thermal conductive pipes, due to the compression by the fixing plate and the retainer; therefore, the engagements between the thermal conductive pipes and the annular walls are greatly enhanced by the increasing engaging contact areas. Thereby, the heat dissipating effect of the thermal fin module is improved, so as to rapidly dissipate the heat of the thermal conductive pipes.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of fabricating a heat dissipating device, comprising:
mounting a first thermal fin module made by pressing and stacking a plurality of fins on thermal conductive pipes;
setting a retainer on a top surface of the first thermal fin module, and compressing the first thermal fin module, so as to reduce a distance between two fins of the first thermal fin module;
mounting a second thermal fin module made by pressing and stacking a plurality of fins on thermal conductive pipes to locate above the first thermal fin module;
mounting a fixing plate above the second thermal fin module on the thermal conductive pipes; and
securing the fixing plate on the second thermal fin module, so as to securely fix the first and the second thermal fin modules with the thermal conductive pipes.

2. The method as claimed in claim 1, wherein a plurality of through hole are formed on the fins corresponding to locations of the thermal conductive pipes, respectively, an annular wall with tapered shape is formed on each through hole by a drawing process, and a pressing portion extending from a narrow top of the taper portion.

3. The method as claimed in claim 2, wherein the pressing portion of a lower fin is embedded into a gap between the thermal conductive pipe and the taper portion of an upper fin during compressing the thermal fin module, so as to reduce the distance between two fins of the thermal fin module.

4. The method as claimed in claim 1, wherein a layer of thermal conductive material for lubricating is pasted on the surface of the thermal conductive pipe before assembling the thermal conductive pipe with the fins.

5. The method as claimed in claim 1, wherein a layer of adhesive material is pasted on the sidewall of a hole formed on the fixing plate or the retainer before the fixing plate or the retainer is set on the thermal conductive pipes, so as to increase the adhesion between the thermal conductive pipe and the fixing plate or the retainer.

6. A heat dissipating device, comprising:
at least one thermal conductive pipe;
a plurality of thermal fin modules, each made of a plurality of fins by pressing and stacking, mounted on the thermal conductive pipe by a through hole correspondingly formed on each fin;
a retainer located between each two thermal fin modules; and
a fixing plate, set on at least one side of the thermal fin modules, wherein the fixing plate is thicker than each fin, and a hole is formed on the fixing plate for mounting on the thermal conductive pipe.

7. The heat dissipating device as claimed in claim 6, wherein an annular wall comprising a taper portion surrounding around the top of the through hole and a pressing portion extending from the taper portions is formed on the through hole.

8. The heat dissipating device as claimed in claim 6, wherein a layer of thermal conductive material for lubricating is paste on a gap between the thermal conductive pipe and the through holes of the fins.

9. The heat dissipating device as claimed in claim 6, wherein a layer of adhesive material is pasted on the gap between the thermal conductive pipe and the hole of the fixing plate.

10. The heat dissipating device as claimed in claim 6, wherein the fixing plate is installed on the top of the thermal fin modules.

11. The heat dissipating device as claimed in claim 6, wherein two fixing plates are installed on the top and the bottom of the thermal fin modules.

12. The heat dissipating device as claimed in claim 6, wherein the thermal conductive pipe is a U-shaped tube, and a cross section of the tube is a circle, an ellipse, or a rectangle.

13. The heat dissipating device as claimed in claim 11, wherein the thermal conductive pipe is a water pipe or a heat pipe.
